(19) United States
(12) Patent Application Publication
(10) Pub. No.: US 2006/0011330 A1
(43) Pub. Date: Jan. 19, 2006

(54) Heat dissipating device

(76) Inventor: Liang-Hua Wang, Taipei City (TW)

Correspondence Address: Ladas & Parry, Suite 2100, 5670 Wilshire Boulevard, Los Angeles, CA, 90036-5679, US

(21) Appl. No.: 10/953,811

(22) Filed: Sep. 28, 2004

(30) Foreign Application Priority Data
Jul. 13, 2004 (TW) 093210992

(51) Int. Cl. H05K 7/20

(52) U.S. Cl. 165/122; 361/687

(57) ABSTRACT

A heat dissipating device includes an air flow tube having a mounting hole between an air inlet and an air outlet, a heat-conducting member mounted in the mounting hole in the air flow tube and adapted to be disposed in close proximity with a heat-generating component, and a fan unit mounted in the air outlet of the air flow tube and operable so as to draw air into the air flow tube via the air inlet for cooling the heat-conducting member in the mounting hole and to expel air in the air flow tube via the air outlet.

### CROSS-REFERENCE TO RELATED APPLICATION

This application claims priority of Taiwanese Application No. 093210992, filed on Jul. 13, 2004.

### BACKGROUND OF THE INVENTION

1. Field of the Invention

The invention relates to a heat dissipating device, more particularly to a heat dissipating device having a relatively high heat-dissipating efficiency.

2. Description of the Related Art

FIG. 1 illustrates a conventional heat dissipating device for dissipating heat generated by a heat-generating device 1, such as a CPU. The conventional heat dissipating device includes a base plate 11 and a plurality of parallel heat-dissipating fin plates 12. The base plate 11 has an upper surface, and a lower surface coated with thermal conducting paste 10 and disposed to conduct heat from the heat-generating device 1. Each of the fin plates 12 extends from the top surface of the base plate 11. In such a configuration, the conventional heat dissipating device is not able to dissipate efficiently heat generated by a CPU with a high processing speed.

### SUMMARY OF THE INVENTION

Therefore, the object of the present invention is to provide a heat dissipating device that can provide a relatively high heat-dissipating efficiency.

According to the present invention, a heat dissipating device comprises:

an air flow tube having an air inlet, an air outlet, and a mounting hole between the air inlet and the air outlet;

a heat-conducting member mounted in the mounting hole in the air flow tube and adapted to be disposed in close proximity with a heat-generating component; and

a fan unit mounted in the air outlet of the air flow tube and operable so as to draw air into the air flow tube via the air inlet for cooling the heat-conducting member in the mounting hole and to expel air in the air flow tube via the air outlet.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic view of a conventional heat dissipating device;

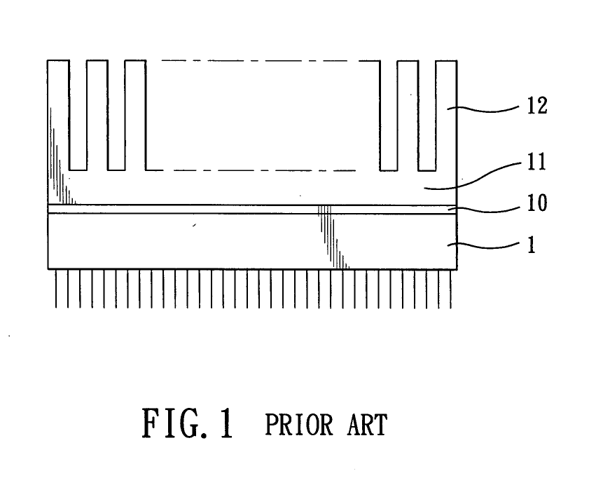

FIG. 2 is an exploded perspective view showing the first preferred embodiment of a heat dissipating device according to the present invention;

FIG. 3 is a schematic sectional view showing the first preferred embodiment;

FIG. 4 is a partly enlarged view of FIG. 3;

FIG. 5 is a fragmentary schematic top view showing the second preferred embodiment of a heat dissipating device according to the present invention;

FIG. 6 is a schematic sectional view showing the third preferred embodiment of a heat dissipating device according to the present invention; and

FIG. 7 is a schematic sectional view showing the fourth preferred embodiment of a heat dissipating device according to the present invention.

### DETAILED DESCRIPTION OF THE PREFERRED EMBODIMENTS

Before the present invention is described in greater detail, it should be noted that like elements are denoted by the same reference numerals throughout the disclosure.

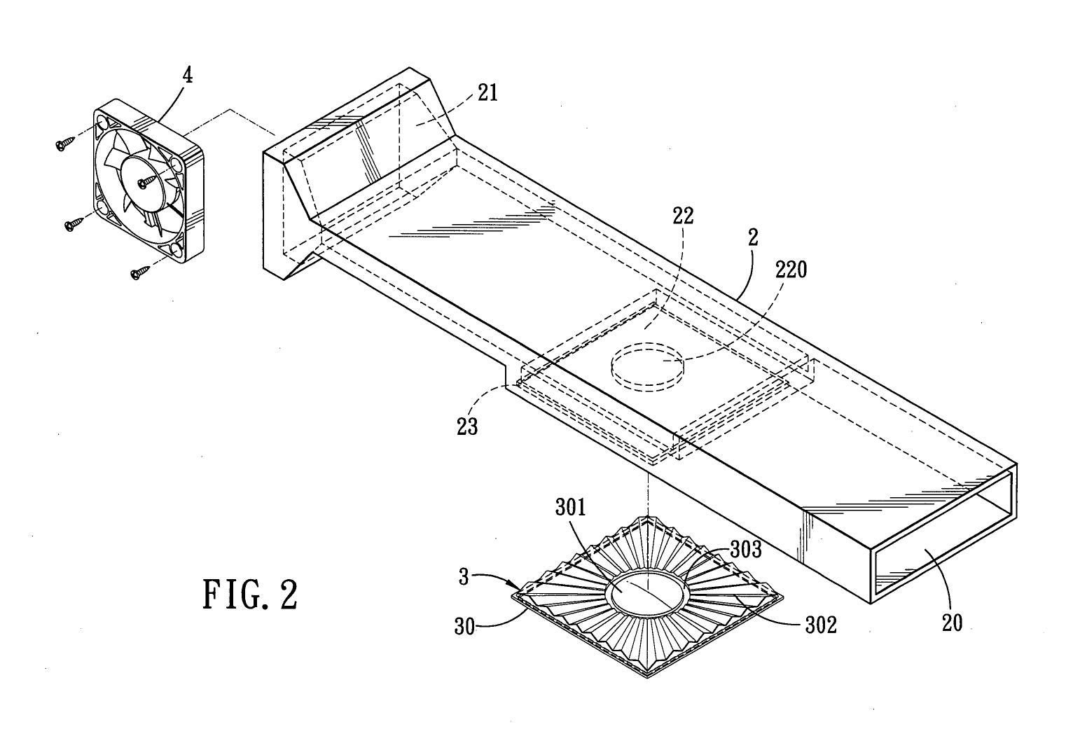

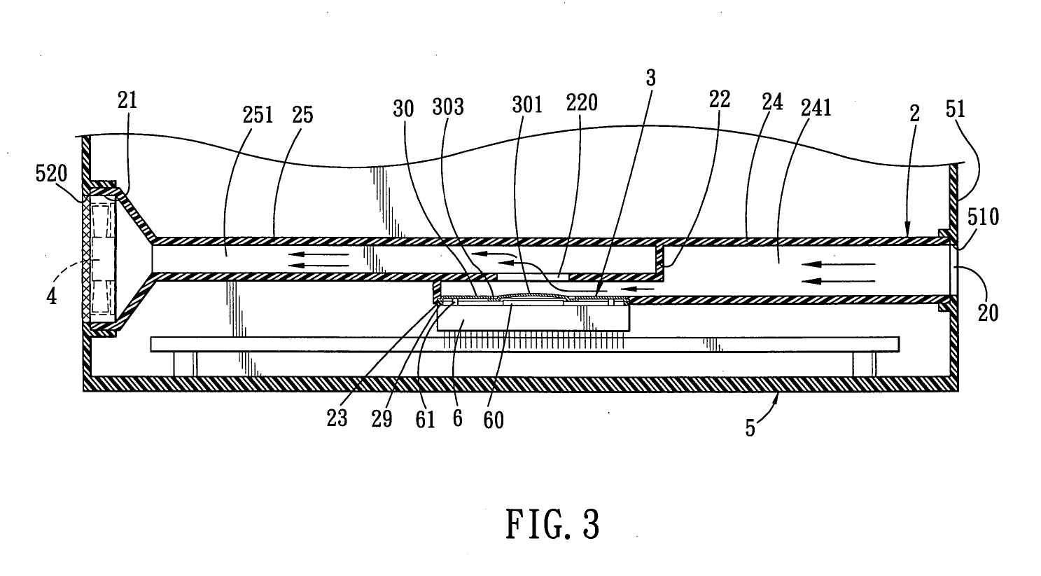

Referring to FIGS. 2 and 3, the first preferred embodiment of a heat dissipating device according to the present invention is shown to include an elongate air flow tube 2, a heat-conducting member 3, and a fan unit 4. In this embodiment, the heat-dissipating device is adapted to be mounted in a housing 50 of an electronic apparatus, such as a notebook computer, for dissipating heat generated by a heat-generating device, such as a CPU 6. The CPU 6 has an exposed die portion 60.

The air flow tube 2, which is made of a dielectric and heat-isolating material, has an air inlet 20 that is in fluid communication with an opening 510 in the housing 51, an air outlet 21 that is in fluid communication with an opening 520 in the housing 5, and a mounting hole 23 between the air inlet 20 and the air outlet 21. In this embodiment, the air flow tube 2 is provided with an inner partition wall 22 therein for dividing the air flow tube 2 into a first tube portion 24 that has the air inlet 20 and that is formed with the mounting hole 23, and a second tube portion 25 that has the air outlet 21. The first tube portion 24 cooperates with the inner partition wall 22 so as to confine a first inner space 241. The second tube portion 25 cooperates with the inner partition wall 22 so as to confine a second inner space 251. The inner partition wall 22 is formed with a through hole 220 that is disposed adjacent to the mounting hole 23 and that permits fluid communication between the first and second inner spaces 241, 251 therethrough.

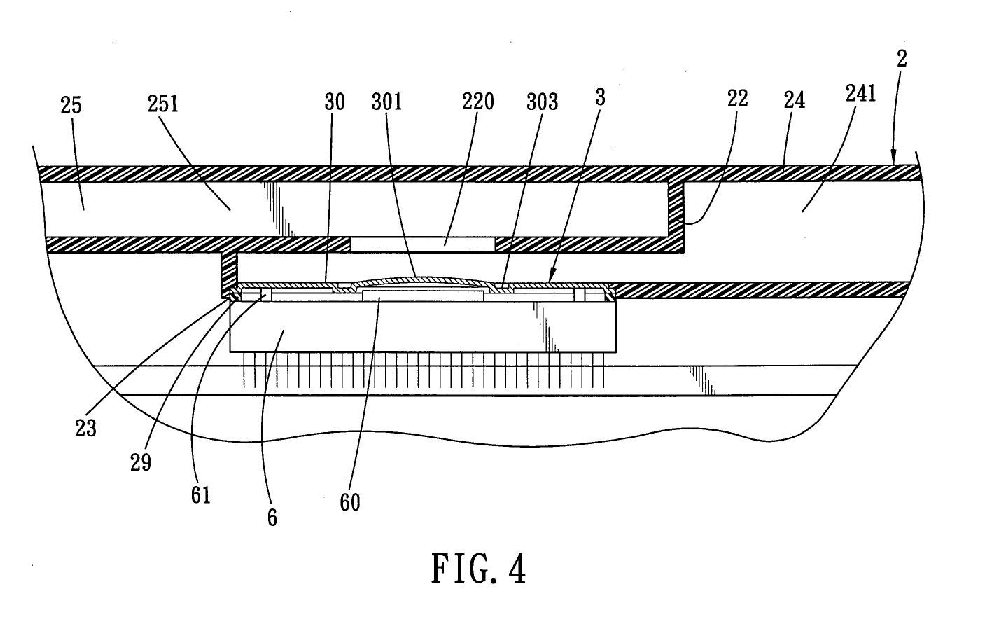

The heat-connecting member 3 is mounted in the mounting hole 23 in the air flow tube 2, is adapted to be disposed in close proximity with the CPU 6, and is supported by a plurality of posts 61 on the CPU 6. In this embodiment, the heat-connecting member 3 is a rectangular metal plate 30 that is made of aluminum and that is punched to form a central projection 301 projecting toward the through hole 220 in the inner partition wall 22 and adapted to be disposed in close proximity with the exposed die portion 60 of the CPU 6, an annular groove 303 surrounding the central projection 301, and a plurality of ribs 302 extending radially from the annular groove 303, as best shown in FIG. 4. Each rib 302 has an inverted-V shaped cross section.

The fan unit 4 is mounted in the air outlet 21 of the air flow tube 2, and is operable so as to draw external air into the air flow tube 2 via the air inlet 20 for cooling the heat-conducting member 3 in the mounting hole 23 and to expel air in the air flow tube 2 via the air outlet 21. As such, heat conducted from the CPU 6 to the heat conducting member 3 can be effectively dissipated, thereby resulting in a relatively high heat-dissipating efficiency.

The heat dissipating device further includes a gasket 29 to retain the heat-conducting member 3 in the mounting hole 23.

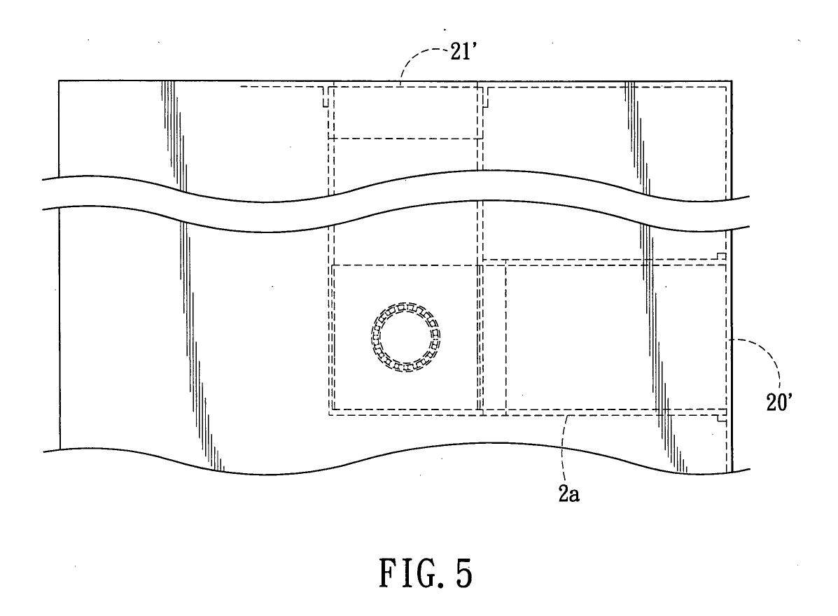

FIG. 5 illustrates the second preferred embodiment of a heat dissipating device according to this invention, which is a modification of the first preferred embodiment. Unlike the previous embodiment, the air flow tube (2a) is L-shaped. The air inlet 20′ and the air outlet 21′are disposed at opposite ends of the air flow tube (2a).

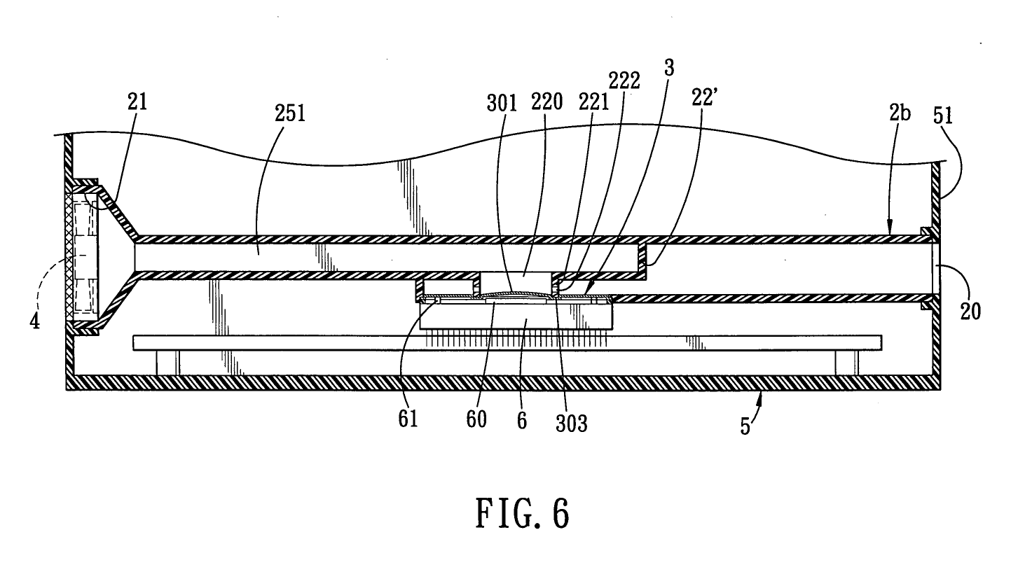

FIG. 6 illustrates the third preferred embodiment of a heat dissipating device according to this invention, which is modification of the first preferred embodiment. In this embodiment, the inner partition wall 22′ of the air flow tube (2b) is provided with a surrounding wall 221 that extends from a periphery of the through hole 220 to the annular groove 303 in the heat-conducting member 3. The surrounding wall 221 is formed with a plurality of radial vent holes 222. As such, during operation of the fan unit 4, air in the first inner space 241 can be effectively guided toward the second inner space 251 by the surrounding wall 221, thereby resulting in a relatively good heat-dissipating efficiency.

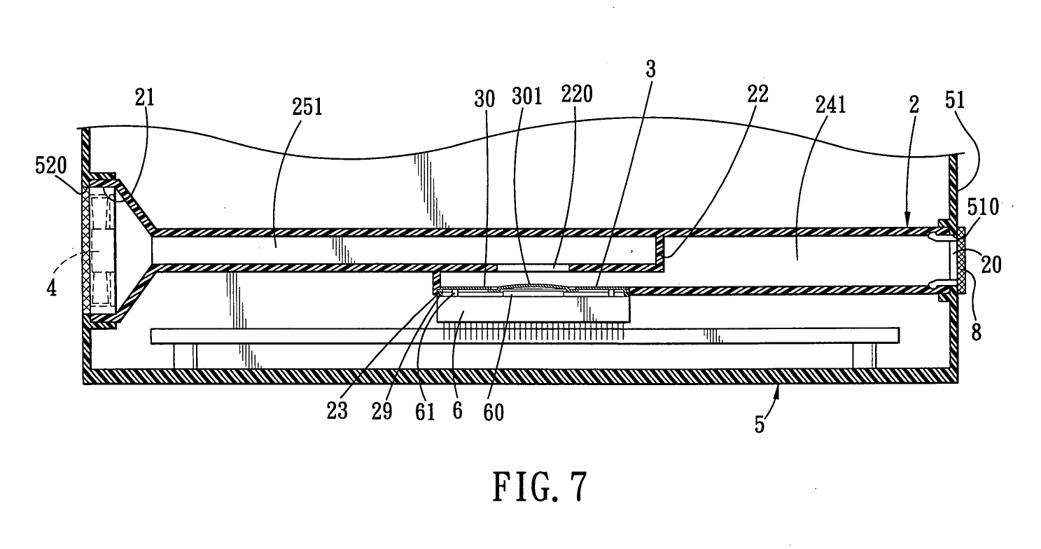

FIG. 7 illustrates the fourth preferred embodiment of a heat dissipating device according to this invention, which is modification of the first preferred embodiment. In this embodiment, the heat dissipating device further includes an air filter layer 8 installed in the air inlet 20 of the air flow tube 2 so as to prevent dust from entering into the air flow tube 2.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A heat dissipating device comprising:
an air flow tube having an air inlet, an air outlet, and a mounting hole between said air inlet and said air outlet;
a heat-conducting member mounted in said mounting hole in said air flow tube and adapted to be disposed in close proximity with a heat-generating component; and
a fan unit mounted in said air outlet of said air flow tube and operable so as to draw air into said air flow tube via said air inlet for cooling said heat-conducting member in said mounting hole and to expel air in said air flow tube via said air outlet.

2. The heat dissipating device as claimed in claim 1, wherein said air flow tube is provided with an inner partition wall therein for dividing said air flow tube into a first tube portion that has said air inlet and that is formed with said mounting hole, and a second tube portion that has said air outlet, said first tube portion cooperating with said inner partition wall so as to confine a first inner space, said second tube portion cooperating with said inner partition wall so as to confine a second inner space, said inner partition wall being formed with a through hole that is disposed adjacent to said mounting hole and that permits fluid communication between said first and second inner spaces therethrough.

3. The heat dissipating device as claimed in claim 1, further comprising a gasket to retain said heat-conducting member in said mounting hole.

4. The heat dissipating device as claimed in claim 2, wherein said heat-conducting member is a rectangular metal plate that is formed with a central projection projecting toward said through hole in said inner partition wall, an annular groove surrounding said central projection, and a plurality of ribs extending radially from said annular groove.

5. The heat dissipating device as claimed in claim 4, wherein said heat conducting member is made of aluminum and is punched to form said central projection, said annular groove, and said ribs.

6. The heat dissipating device as claimed in claim 4, wherein each of said ribs has an inverted-V shaped cross section.

7. The heat dissipating device as claimed in claim 1, wherein said air flow tube is L-shaped, and said air inlet and said air outlet are disposed at opposite ends of said air flow tube.

8. The heat dissipating device as claimed in claim 4, wherein said inner partition wall is provided with a surrounding wall that extends from a periphery of said through hole to said annular groove in said heat-conducting member, said surrounding wall being formed with a plurality of radial vent holes.

9. The heat dissipating device as claimed in claim 1, further comprising an air filter layer installed in said air inlet of said air flow tube.
